(19) United States
(12) Patent Application Publication
(10) Pub. No.: US 2009/0139658 A1
(43) Pub. Date: Jun. 4, 2009

(54) PLASMA PROCESSING APPARATUS

(75) Inventors: Leslie Michael LEA, Oxfordshire (GB); Jyoti Kiron BHARDWAJ, Bristol (GB); Edward GUIBARRA, Cardiff (GB)

Correspondence Address: VOLENTINE & WHITT PLLC, ONE FREEDOM SQUARE, 11951 FREEDOM DRIVE SUITE 1260, RESTON, VA, 20190, US

(73) Assignee: SURFACE TECHNOLOGY SYSTEMS PLC, Gwent (GB)

(21) Appl. No.: 11/758,959

(22) Filed: Jun. 6, 2007

Related U.S. Application Data
(63) Continuation of application No. 09/462,263, filed on Mar. 23, 2001.

(30) Foreign Application Priority Data
Jul. 9, 1997 (GB) 9714341.6
Oct. 24, 1997 (GB) 9722408.3

(51) Int. Cl. C23F 1/00; C23C 16/00

(52) U.S. Cl. 156/345.41; 118/723 R; 118/723 MW; 118/723 I; 156/345.48; 156/345.1

(57) ABSTRACT

A slotted conducting cylinder (11) surrounds a reactor chamber body (10) and is in turn surrounded by an antenna (12). The cylinder (11) can be grounded during normal operation of plasma processing apparatus, but when RF driven it serves to enhance capacitive coupling with the plasma causing the inner surface (16) of the body (10) to become charged and hence the plasma will sputter clean the inner surface (16).

### CROSS-REFERENCE TO RELATED APPLICATIONS

This is a continuation of application Ser. No. 09/462,263, filed Mar. 23, 2000, which is incorporated herein by reference in its entirety, which is a U.S. national stage filing of International Application No. PCT/GB98/01802, filed Jul. 8, 1998.

### SUMMARY

Inductively coupled plasma sources require an antenna to couple the RF or other alternating current power into the plasma. This antenna can either be within the chamber in which the plasma is struck, and provided with an insulating coating or other shielding, or located outside the chamber, close to a dielectric window. The insulation is required to prevent direct electrical contact between the antenna and the plasma.

When the source is used for the deposition of an element or compound on a work place located within it, the substance will also be deposited on the inside of the source. Also during etching, where the ion impact plays a significant role, material is ejected from the surface of the work piece and is deposited onto the surfaces of the chamber. When the antenna is located on the outside of a dielectric window, the substance will be deposited on the vacuum face of that window. Furthermore, condensation of plasma/gas phase reactants may also coat the dielectric window. The interior of the chamber will require cleaning at regular intervals to remove the substance and prevent particles “flaking” off the walls and falling on the work piece, with the potential for damage to the work piece. In addition, conducting or semiconducting film deposited on the dielectric window will progressively reduce the efficiency with which RF power is inductively coupled into the plasma.

The cleaning of the metallic walls of the chamber and its furniture will usually be carried out by hand using a mildly abrasive material. It is generally more difficult to clean the dielectric window, which is typically constructed out of alumina, quartz or a similar material, often requiring the use of specialised mechanical abrasive or chemical cleaning.

The invention consists of plasma processing apparatus including a chamber, means for inducing a plasma in the chamber, means for shielding the induction means from the induced plasma and shield cleaning means comprising electrically conducting means extending over the shielding means on the induction means side thereof and an alternating current power supply connectable to the conducting means for coupling the conducting means to the plasma for causing the plasma side of the shielding to become negatively charged.

The induction means may be an antenna, eg. an RF antenna, or it may be a microwave source.

In one arrangement the conducting means may include at least one window for enhancing coupling of the induction means to the plasma. Thus where the antenna is the induction means there are preferably a plurality of spaced windows along at least part of the length of the conducting means. The window or windows may be in the form of slots, which are preferably orthogonal to the axis of the conductor forming the antenna. The apparatus may further include electrically conducting shutter means for closing the window or windows when the electrically conducting means is connected to its power source.

Additionally or alternatively the conducting means may be movable relative to the induction means and the chamber between a cleaning position, in which it is interposed between the induction means and the chamber and a withdrawn position. In this case motor means may be provided for moving the conductor means between the two locations.

The invention alternatively comprises plasma process apparatus including a chamber, an antenna for inducing a plasma in a chamber and a power supply means for supplying power to the antenna in a first, cleaning, mode to couple capacitively the power to the plasma and a second, processing, mode to couple inductively the power to the plasma.

Alternatively the invention could be expressed as operating the antenna as an electrode in the cleaning mode and as an antenna in the inductive mode. The invention also includes methods of processing using such a method of operation.

In any of the above arrangements the power supply may be an RF power supply.

Although the invention has been defined above it is to be understood that it includes any inventive combination of the features set out above or in the following description.

### BRIEF DESCRIPTION OF THE DRAWINGS

The invention may be performed in various ways and specific embodiments will now be described, by way of example, with reference to the accompanying drawings, in which:

FIG. 1 is schematic view from above of part of a plasma processing apparatus;

FIG. 2 is a perspective view of FIG. 1;

FIG. 3 is a cross section through an alternative antenna/dielectric window arrangement;

FIG. 4 is a scrap view illustrating more clearly the conducting element of FIG. 3;

FIG. 5 is a schematic view of microwave apparatus incorporating shielding cleaning means;

FIGS. 6 and 7 show schematically the working and cleaning configurations; and

FIG. 8 is a circuit diagram combining the circuits of FIGS. 6 and 7.

### DETAILED DESCRIPTION

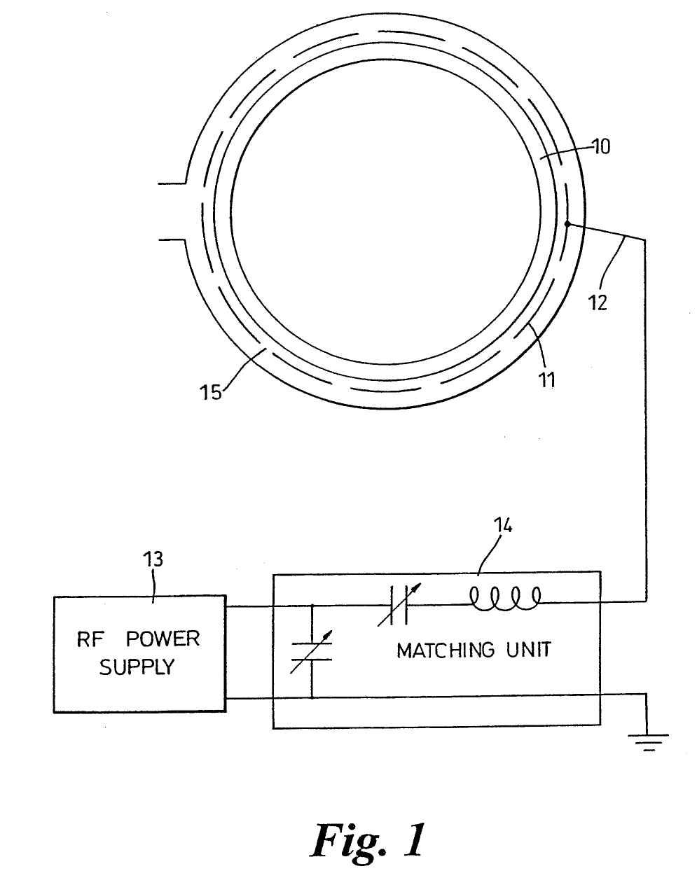

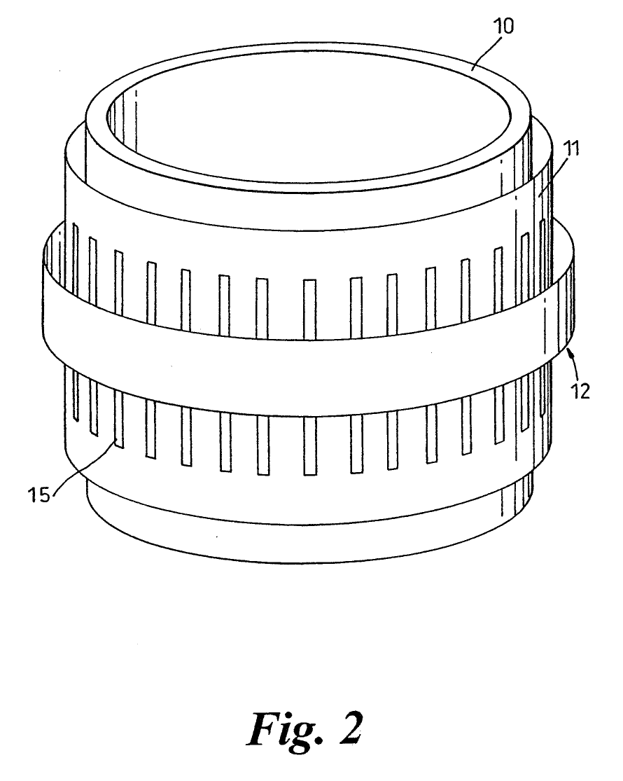

In FIGS. 1 and 2 the cylindrical body 10 of the chamber of plasma processing apparatus is formed from dielectric material. This in turn in surrounded by a conducting cylinder 11 which lies between the dielectric window 10 and a single turn antenna 12. As has been described above, the antenna 12 can be fed from an RF power supply (not shown) to induce a plasma within the chamber. The cylinder 11 is also connected to an RF power supply 13 via a matching unit 14. The cylinder 11 has a series of vertically extending and circumferentially spaced slots 15.

The provision of the conducting cylinder 11 located against atmospheric face of the dielectric window 10, when driven from an RE supply 13, will capacitively couple power to a plasma created within the chamber. Grounded conducting components of the chamber, which are, in contact with the plasma will act to provide a return path. Provided that the area of the driven conductor 11 is small in comparison with the area of the grounded conducting components, the inner surface 16 of the dielectric window 10 will charge to an appreciable negative DC potential with respect to the plasma. Ions will then be extracted from the plasma and will bombard the dielectric window. With argon or other appropriate gas used to form the plasma, the ions will sputter deposited material from the window and therefore provide a method for cleaning the window. Gases which allow a chemical component to enhance the physical removal of the deposit may also be used.

The conducting cylinder 11 must clearly not significantly interfere with the inductive coupling of power from the antenna 12 to the process plasma during normal operation of the source. In order for this to be true the inductive coupling between the antenna and the conducting sheet must be reduced. This is achieved by the slots 15 in the conducting sheet whose major axis is perpendicular to the local coil direction. The slot width is a trade off between minimum interference to the inductive coupling process, requiring a wide slot, and the need for a narrow slot so that a bias is applied over much of the dielectric window to attract ions for the cleaning process. With slots at 20 mm spacing, the slot width should be a minimum of 2 mm to allow reasonably efficient coupling of inductive power into a process plasma.

When the slotted conducting cylinder 11 is not being used for the cleaning process, it should be grounded. Alternatively it could be withdrawn in which case slots would not be required. When grounded the cylinder 11 can then have the additional desirable effect of reducing the capacitive coupling of RF power from the antenna into the normal process plasma.

For the cleaning process, the gas pressure within the source will typically be in the range of a few mTorr to a few hundred mTorr. At the higher pressures, ion scattering from the neutral gas will increase the area cleaned beyond that corresponding directly to the profile of the conducting sheet, but will reduce the average ion energy. An alternative to ensure that the whole of the dielectric window is cleaned, when the conducting sheet is of a slotted form, is to move the conducting sheet parallel to the surface of the window and perpendicular to the major axis of the slot. In another arrangement shutters (not shown) may be added to close the slots 15 during cleaning.

To initiate a plasma particularly at low pressures, some degree of capacitive coupling of RF is required. The slotted conductive sheet may then be used to assist in initiating the normal process plasma, by temporarily switching off the ground connection and driving it from a source of RF power.

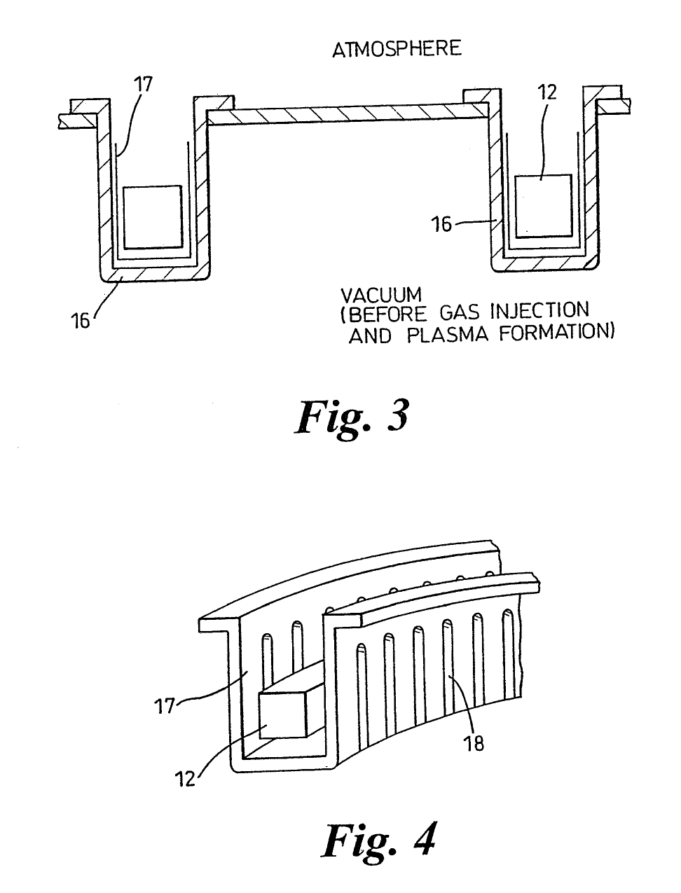

FIG. 3 illustrates an alternative arrangement in which the antenna 12 sits in a dielectric trough 16 and an electrically conducting trough 17 is interposed between the antenna 12 and the dielectric trough 16. As can be seen in FIG. 4 the trough 17 should be slotted. One such slot is indicated at 18.

Separate RF supplies can be provided for the antenna 12 and the electrically conducting element 11, 17 of both can be powered from the same source. In the first case the shield cleaning can take place at the same time as the antenna is in operation to enhance machine cycle time.

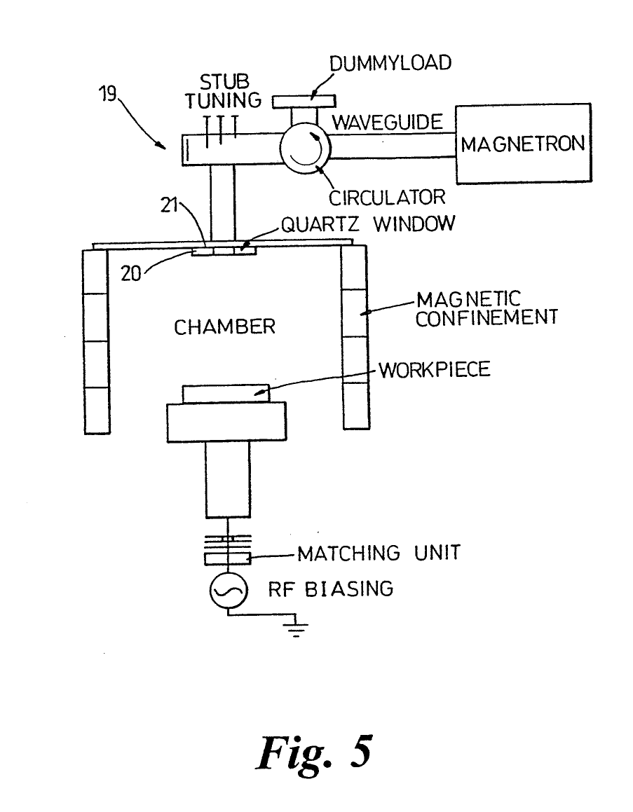

FIG. 5 illustrates an arrangement wherein the plasma is induced by a microwave source 19 that operates through a quartz window 20. Shield cleaning means can again be provided for example by a deposited electrically conducting layer 21, which is provided with slots or windows of sufficient dimension to avoid microwave attenuation.

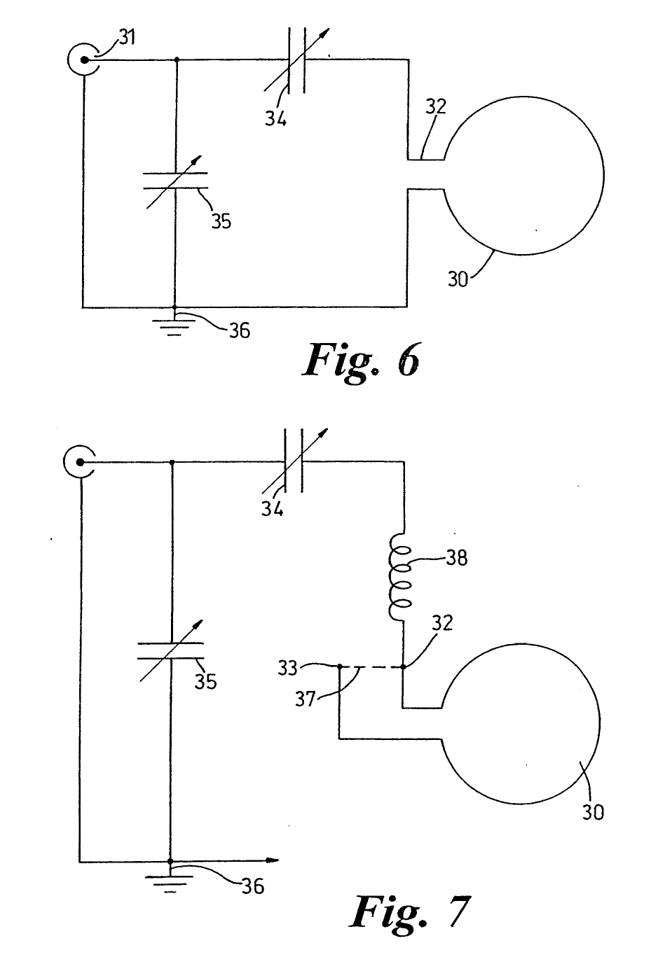

In FIG. 6 the antenna 30 is shown configured for inductively coupling power into the plasma used during normal operation in which a work piece is being processed. Thus the RF power is supplied at 31 across the ends 32, 33 of the antenna 30 via a series variable capacitor 34 with a parallel variable capacitor 35 connected across the power supply feed 31. End 33 of the antenna is earthed at 36.

FIG. 7 shows the necessary re-configuration of the electrical connections to the antenna 30 in order to allow it to be used for cleaning of the vacuum side of the window. Essentially the end 33 is either allowed to float or, alternatively, it may be connected to end 32 as shown in dotted line at 37 and a series inductor 38 is introduced between capacitor 34 and 32.

These Figures provide an example and are not intended to prelude other alternative methods of configuring the antenna 30 during normal plasma processing nor other methods of configuring the antenna during the cleaning operation. In particular during normal plasma processing, the antenna may not be directly grounded at one end an may be either directly or effectively grounded at another point. These Figures show a single turn circular antenna coil, but is not intended to preclude the use of antennae which comprise multiple turn coils of any physical shape or size.

The change in the electrical configuration between the FIGS. 6 and 7 results in the change from an antenna 30 which is effective at inductively coupling power into a plasma, (see FIG. 6) (with a local capacitive coupling component related to the local potential on the antenna), to an electrode 30 which is biased throughout to essentially the same potential (see FIG. 7) and therefore only capacitively couples power into a plasma.

The plasma formed by the inductive coupling of RF power and used for processing of work pieces, is of high density, with only a small AC component to the plasma potential and only a small DC potential difference between the plasma and the walls of the chamber. In contrast, the plasma formed by the capacitive coupling of RF power, and used for the in situ cleaning of the window, is of lower density with a larger AC component to the plasma potential. The capacitive coupling of power by the driven antenna leads to negative biassing of the plasma side of the window surface with respect to grounded components of the chamber. Positive ions are then attracted from the plasma to bombard the surface of the window causing physical sputtering of previously deposited material and therefore removal of that material. The cleaning process may be enhanced under some circumstances by chemical processes.

As well as being applicable to sources utilising a single antenna for inductively coupling power into a process plasma, the technique may be applied to plasma sources in which two or more antennae are used. The cleaning of each window may then be carried out independently using separate RF power supplies, or by use of an electrical network which enables all, or certain combinations of the windows to be cleaned at the same time.

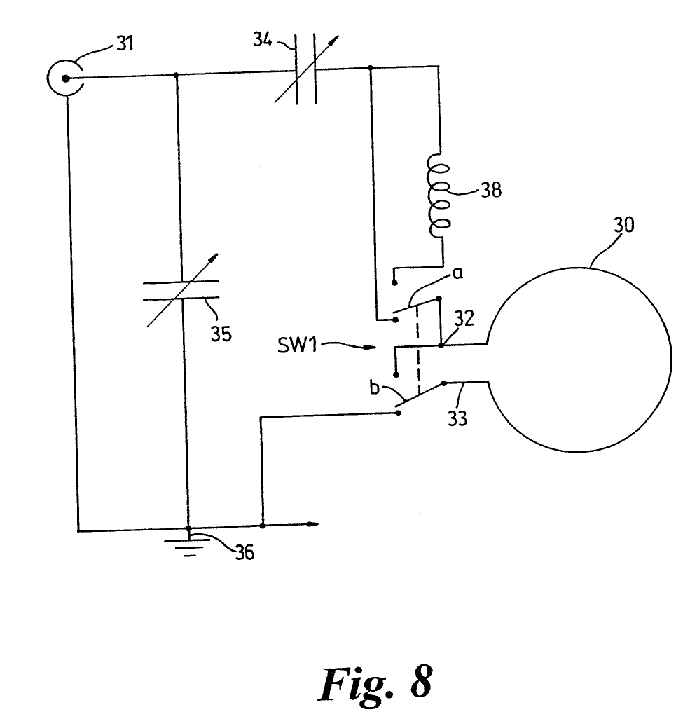

FIG. 8 shows an example of a circuit to match the power from an RF generator to an antenna 30 which inductively couples the power into a process plasma. The circuit will also allow the antenna 30 to be used as an electrode for running the capacitively coupled plasma which may be used for cleaning the plasma side of the window between the antenna and the interior of the plasma source.

In FIG. 8 the switch SW1 is a two-pole two-way switch. As shown both pole a and b shown in position for running an inductively coupled process plasma. For operating a capacitively coupled plasma for cleaning the window, both poles of the switch must be changed to the alternative state. For the capacitively coupled plasma SW1b operates to disconnect the grounding of end 33 of the antenna 30 and also to join together both ends 32, 33 of the antenna 30. The disconnection from ground 36 is essential but the joining together of both ends 32, 33 of the antenna 30 may not always be necessary.

The switch SW1 must be capable of handling the appropriate voltages and currents found in the circuit when operating at the required RF frequency. In general to minimize the length of wires and allow the complete RF circuit to be electrically screened, the RF switch will take the form of a relay operated by a suitable control voltage. As shown, the antenna is grounded at one side when used to drive an inductively coupled plasma. For a process plasma, a balanced feed transformer, for example as described in our PCT Application No. PCT/GB98/01769 filed on 6th July entitled Plasma Processing Apparatus, which is incorporated herein by reference, may be used for driving the inductively coupled plasma.

What we claim is:

1. Plasma processing apparatus including a chamber means for inducing plasma in the chamber, means for shielding the induction means from the induced plasma and shielding cleaning means comprising electrically conducting means extending over the shielding means on the induction means side thereof and an alternating current power supply connectable to the conducting means for coupling the conducting means to the plasma for causing the plasma side of the shielding to become negatively charged.

2. Apparatus as claimed in claim 1 wherein the induction means is an antenna or a microwave source.

3. Apparatus as claimed in claim 1 wherein the conducting means includes at least one window for enhancing coupling of the induction means to the plasma.

4. Apparatus as claimed in claim 3 wherein the induction means is an antenna and there are a plurality of spaced windows along at least part of the length of the conducting means.

5. Apparatus as claimed in claim 2 wherein the window or windows are in the form of slots.

6. Apparatus as claimed in claim 2 further including electrical conducting shutter means for closing the window or windows when the electrically conducting means is connected to its power source.

7. Apparatus as claimed in claim 1 wherein in the conducting means is movable relative to the induction means and the chamber between a cleaning position, in which it is interposed between the induction means and the chamber, and a withdrawn position.

8. Plasma processing apparatus including a chamber, an antenna for inducing a plasma in a chamber and a power supply means for supplying power to the antenna is a first, cleaning mode to couple capacitively the power to the plasma and a second, processing, mode to couple inductively the power to the plasma.

9. Apparatus as claimed in claim 8 wherein the power supply means biases the antenna to essentially the same potential throughout so that it acts as an electrode.

10. Apparatus as claimed in claim 8 including switching means for switching the power supply means between modes.

11. Apparatus as claimed in claim 1 wherein the power supply is an RF power supply.

12. Apparatus as claimed in claim 8 wherein the power supply is an RF power supply.
